(19) United States
(12) Patent Application Publication
(10) Pub. No.: US 2010/0236628 A1
(43) Pub. Date: Sep. 23, 2010

(54) Composition and method of forming an insulating layer in a photovoltaic device

(76) Inventors: Chris Schmidt, Redwood City, CA (US); Bruce Hachtmann, San Martin, CA (US)

Correspondence Address: FOLEY AND LARDNER LLP;SUITE 500, 3000 K STREET NW, WASHINGTON, DC, 20007, US

(21) Appl. No.: 12/382,498

(22) Filed: Mar. 17, 2009

(51) Int. Cl. H01L 31/0328; H01L 31/0272; C23C 14/38

(52) U.S. Cl. 136/262; 136/264; 438/95; 204/192.22; 204/298.13; 257/E31.008

(57) ABSTRACT

A solar cell includes a first electrode located over a substrate, at least one p-type semiconductor absorber layer located over the first electrode, the p-type semiconductor absorber layer comprising a copper indium selenide (CIS) based alloy material, an n-type semiconductor layer located over the p-type semiconductor absorber layer, an insulating aluminum zinc oxide layer located over the n-type semiconductor layer, the insulating aluminum zinc oxide having an aluminum content of 100 ppm to 5000 ppm and a second electrode over the insulating aluminum layer, the second electrode being transparent and electrically conductive. The insulating aluminum zinc oxide having an aluminum content of 100 ppm to 5000 ppm, may be deposited by pulsed DC, non-pulsed DC, or AC sputtering from an aluminum doped zinc oxide having an aluminum content of 100 ppm to 5000 ppm.

### FIELD OF THE INVENTION

The present invention relates generally to the field of photovoltaic devices, and more specifically to thin-film solar cells having an insulating layer located between a p-n junction and a top electrode.

### BACKGROUND OF THE INVENTION

Copper indium diselenide (CuInSe₂, or CIS) and its higher band gap variants copper indium gallium diselenide (Cu(In,Ga)Se₂, or CIGS), copper indium aluminum diselenide (Cu(In,Al)Se₂), copper indium gallium aluminum diselenide (Cu(In,Ga,Al)Se₂), and any of these compounds with sulfur replacing some of the selenium represent a group of materials, referred to as copper indium selenide CIS based alloys, have desirable properties for use as the absorber layer in thin-film solar cells. To function as a solar absorber layer, these materials should be p-type semiconductors. This may be accomplished by establishing a slight deficiency in copper, while maintaining a chalcopyrite crystalline structure. In CIGS, gallium usually replaces 20% to 30% of the normal indium content to raise the band gap; however, there are significant and useful variations outside of this range. If gallium is replaced by aluminum, smaller amounts of aluminum are used to achieve the same band gap.

### SUMMARY OF THE INVENTION

One embodiment of this invention provides a solar cell including a first electrode located over a substrate, at least one p-type semiconductor absorber layer located over the first electrode, the p-type semiconductor absorber layer comprising a copper indium selenide (CIS) based alloy material, an n-type semiconductor layer located over the p-type semiconductor absorber layer, an insulating aluminum zinc oxide layer located over the n-type semiconductor layer, the insulating aluminum zinc oxide having an aluminum content of 100 ppm to 5000 ppm and a second electrode over the insulating aluminum layer, the second electrode being transparent and electrically conductive.

Another embodiment of the invention provides a method of manufacturing a solar cell, including depositing a first electrode over a substrate, depositing at least one p-type semiconductor absorber layer over the first electrode, the p-type semiconductor absorber layer comprising a copper indium selenide (CIS) based alloy material, depositing an n-type semiconductor layer over the p-type semiconductor absorber layer to form a p-n junction, depositing an insulating aluminum zinc oxide layer located over the n-type semiconductor layer, the insulating aluminum zinc oxide having an aluminum content of 100 ppm to 5000 ppm, and depositing a second electrode over the n-type semiconductor layer, the second electrode being transparent and electrically conductive.

Another embodiment of this invention provides a method of depositing an insulating aluminum zinc oxide layer, including pulsed or non-pulsed DC sputtering an aluminum doped zinc oxide target having an aluminum content of 100 ppm to 5000 ppm, where the insulating aluminum zinc oxide layer has a resistance of 100 Ω/□ to 10⁶ Ω/□.

Still another embodiment of this invention provides a sputtering target configured for DC or AC sputtering, containing aluminum doped zinc oxide having an aluminum content of 100 ppm to 5000 ppm.

### BRIEF DESCRIPTION OF THE DRAWINGS

FIG. 1 is a schematic side cross-sectional view of a CIS based solar cell according to one embodiment of the invention.

FIG. 2 shows a highly simplified schematic diagram of a top view of a modular sputtering apparatus that can be used to manufacture the solar cell depicted in FIG. 1.

FIG. 3 illustrates schematically the use of three sets of dual magnetrons to increase the deposition rate and grade the composition of the CIS based layer to vary its band gap.

### DETAILED DESCRIPTION

Solar cells within a module are generally connected in series. Consequently, the solar cell having the poorest performance within the module is at risk of being reverse biased and being overheated. In certain circumstances, the performance of the whole module may be deteriorated because of this overheating. On the other hand, it is not uncommon that one or several cells within a module may be shunted, deteriorating the performance of the module. For example, Meyer (Meyer et al., IEEE 2005, p. 1331-1334) describes the effect of a low shunt resistance. If the shunt resistance is less than 100Ω, then it reduces the stability of the module under partial shading when a mild reverse bias is applied. Thus, thin film photovoltaic devices typically include a very thin insulating zinc oxide layer, for example a thin pure ZnO layer (referred to as intrinsic ZnO or i-ZnO), disposed between the p-n (or p-i-n) junction and the top contact, such as a transparent conductive oxide (TCO) layer (or between a buffer layer which is located on the junction and the top contact), in order to improve the efficiency of the solar cell. Such a thin i-ZnO layer usually has a resistivity of 1 Ω*cm to 10,000 Ω*cm.

Without wishing to be bound by any theory, the i-ZnO layer may function by insulating shunt paths due to defects in the substrate material and/or in the film structure, such as scratches or holes through CIGS layers and by isolating spatial inhomogeneities in the absorber and in the p-n junction. The influence of an intrinsic zinc oxide (i-ZnO) layer of different thicknesses on the solar cell efficiency is disclosed in Ottoson (Ottoson, “The role of i-ZnO for shunt prevention in Cu(In,Ga)Se₂ based solar cells”, Thesis, April 2006, Uppsala University), which is incorporated herein by reference in its entirety.

U.S. Pat. No. 5,078,804 (“Chen”) teaches a structure with an i-ZnO layer of high electrical resistivity (low conductivity) deposited on a buffer layer and an n-type ZnO layer of high conductivity (also referred to as n-ZnO) deposited on the i-ZnO layer. Both i-ZnO and n-ZnO layers are deposited by RF magnetron sputtering in an oxygen-argon atmosphere or a pure argon atmosphere. Similarly, U.S. Pat. No. 6,040,521 (“Kushiya”) describes an RF sputtered i-ZnO layer deposited directly onto a p-type CIGS absorber, followed by depositing a second, DC sputtered, conductive n-ZnO layer on the i-ZnO layer.

Due to the insulating nature, a highly resistive target material, e.g., an i-ZnO target material, may not be sputtered by direct current (DC) or alternating current (AC) sputtering. Thus, radio frequency (RF) sputtering is required for depositing the i-ZnO layer. However, RF sputtering requires large and expensive power supplies, has a relatively low deposition rates, and needs elaborate shielding to reduce radio frequency interference with adjacent deposition chambers and nearby electronic equipments. Moreover, RF plasma generally generates a high degree of ionization which leads to unwanted ion bombardment of the growing film. Finally, RF plasmas may induce a bias voltage on the substrate surface, causing damage to the underlying thin film stack (e.g., inducing migration of copper atoms within the CIS based absorber layer). For these reasons, RF sputtering is not a highly desirable method for high volume manufacturing of thin film CIS based solar devices.

U.S. Publication No. 2009/0014065 (“Mueller”) teaches forming two layers of aluminum doped zinc oxide by AC or DC sputtering from a composite ceramic (e.g., ZnO:Al₂O₃) or metal target containing several percent aluminum (i.e., at least two percent aluminum). A first layer of aluminum doped zinc oxide having a relative high resistivity is sputtered under a relatively oxygen rich sputtering environment, preferably in an inert gas containing ˜1% oxygen, while a second aluminum doped zinc oxide layer having a high conductivity is sputtered in an environment substantially free of oxygen (i.e., inert gas containing less than 0.1% oxygen). Alternatively, Mueller teaches that a metallic target consisting of Zn—Al alloy with several weight percent aluminum may also be used for depositing the first and second layers through reactive sputtering under sputtering environment containing oxygen. The first layer has a resistivity of 1×10⁵ Ω/□ to 2×10⁸ Ω/□, significantly higher than that of the second conductive layer, because the first layer is sputtered in a sputtering environment having a higher oxygen concentration. However, Muller's method results in an insulating aluminum doped zinc oxide layer (the first layer) having a high aluminum concentration, which may diffuse into the n-type semiconductor layer (e.g., CdS layer) of the solar cell and create defects states in the depletion region or the metallurgical junction.

One embodiment of the present invention provides a method of depositing an insulating aluminum zinc oxide layer, comprising sputtering an aluminum doped zinc oxide target having a low aluminum content, for example 100 ppm to 5000 ppm. Unexpectedly, it is found that zinc oxide target material having a low aluminum content of 100 ppm to 1,000 ppm provides a target material conductive enough to be sputtered by DC, pulsed-DC, or AC sputtering, yet such a resulting ZnO layer having a low aluminum content deposited by DC, pulsed-DC, or AC sputtering from aluminum doped zinc oxide target has a sufficiently high electrical resistivity for improving the solar cell efficiency and stability under partial shading. In some embodiments, the step of depositing the insulating aluminum zinc oxide layer comprises pulsed or non-pulsed DC sputtering in a sputter atmosphere containing 1 to 50 volume percent (also referred to as molar percent) of oxygen-containing gas, for example, a sputter atmosphere containing at least 5 volume percent of the oxygen-containing gas, such as 5 to 10 volume percent of the oxygen-containing gas. Any suitable oxygen-containing gas may be used, for example, O₂ or H₂O may be used in some embodiments. Without wishing to be bound by a particular theory, the present inventors believe that the low aluminum concentration may reduce aluminum diffusion into the n-type semiconductor layer (e.g., CdS layer), and thus improve the solar cell performance by reducing defects states in the depletion region or the metallurgical junction generated by aluminum impurities. Further, the low aluminum concentration may improve the band alignment between the CdS and RAZO layer, leading to less recombination at the interface. Finally, the low aluminum concentration may enable lower oxygen flow rates for the same or higher resistivity, leading to less back-sputtering of the deposited film which can damage the sensitive junction between the n-type semiconductor layer and the p-type absorber layer (e.g., the junction between the n-type CdS and p-type CIGS layers).

This method of depositing an insulating aluminum zinc oxide layer by DC, pulsed-DC, or AC sputtering from an aluminum doped zinc oxide target having a low aluminum content, for example 100 ppm to 5000 ppm, may be used for any suitable applications, especially for applications in which a thin insulating film is desired but RF sputtering is not favorable, for example but not limited to fabricating a solar cell having the thin insulating film. The target may have a hollow cylinder shape for being mounted in a rotating target DC or AC sputtering system. Alternatively, the target may be a planar target.

Another embodiment of this invention provides a solar cell comprising a first electrode located over a substrate, at least one p-type semiconductor absorber layer located over the first electrode, the p-type semiconductor absorber layer comprising a CIS based alloy material, an n-type semiconductor layer located over the p-type semiconductor absorber layer, an insulating aluminum zinc oxide layer located over the n-type semiconductor layer, the insulating aluminum zinc oxide having an aluminum content of 100 ppm to 5000 ppm (from 0.01 to 0.5 weight percent) and a second electrode over the insulating aluminum layer, the second electrode being transparent and electrically conductive.

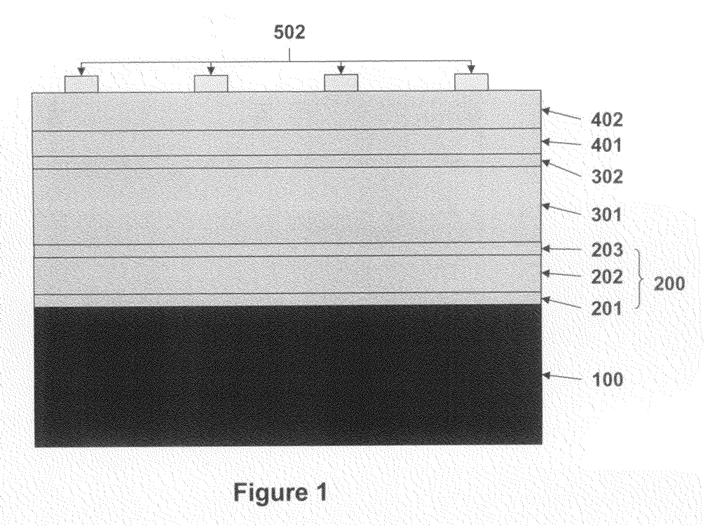

FIG. 1 shows a CIS based solar cell structure of a non-limiting example of this invention. A first electrode 200 is located over a substrate 100. The substrate 100 may comprise any suitable material, for example, metal, plastic material, thermally stable polymer material, such as polyimide, glass or ceramic material or a combination thereof, such as a polymer coated metal substrate. In some embodiment, the substrate 100 may be a metal foil web, for example, stainless steel, aluminum, or titanium foil web.

The first electrode 200 may include a primary conductor layer 202, one or more optional first barrier layers 201 located between the primary conductor layer 202 and the substrate 100, and one or more optional second barrier layers 203 located between the primary conductor layer 202 and a CIS based alloy layer 301. The primary conductor layer 202 may be any suitable conductive material, for example transition metals such as Mo, W, Ta, V, Ti, Nb, Zr, Cu, Ni, Ag, Al, or alloys thereof. The one or more barrier layers 201 and 203 may be any suitable material, for example, a transition metal or metal nitride material, such as Cr, Ti, Nb, TiN, or ZrN.

In preferred embodiments, a p-type semiconductor absorber layer 301 is then deposited over the first electrode 200. The p-type semiconductor absorber layer 301 may comprise a CIS based alloy material selected from copper indium selenide, copper indium gallium selenide, copper indium aluminum selenide, any of these compounds with sulfur replacing some of the selenium, or combinations thereof. Layer 301 may have a stoichiometric composition having a Group I to Group III to Group VI atomic ratio of about 1:1:2, or a non-stoichiometric composition having an atomic ratio of other than about 1:1:2. Preferably, layer 301 is slightly copper deficient and has a slightly less than one copper atom for each one of Group III atom and each two of Group VI atoms. The step of depositing the at least one p-type semiconductor absorber layer may comprise reactively AC sputtering the semiconductor absorber layer from at least two electrically conductive targets in a sputtering atmosphere that comprises argon gas and a selenium containing gas (e.g. selenium vapor or hydrogen selenide). For example, each of the at least two electrically conductive targets comprises copper, indium and gallium; and the CIS based alloy material comprises copper indium gallium diselenide.

An n-type semiconductor layer 302 may then be deposited over the p-type semiconductor absorber layer 301. The n-type semiconductor layer 302 may comprise any suitable n-type semiconductor materials, for example, but not limited to ZnS, ZnSe or CdS, CdTe, or a combination thereof.

Further, the insulating aluminum zinc oxide layer 401 may be deposited by pulsed DC or non-pulsed DC sputtering a zinc oxide target comprising 100 ppm to 5000 ppm aluminum over the n-type semiconductor layer 302. If desired, AC sputtering may be used instead. The deposited layer 401 has an aluminum concentration substantially the same as that of the target, and thus also contains an aluminum content of 100 ppm to 5000 ppm (0.01 to 0.5 weight percent). In some embodiments, the insulating aluminum zinc oxide target and deposited layer 401 have an aluminum content of 100 ppm to 2000 ppm, such as 500 ppm to 1200 ppm. The insulating aluminum zinc oxide layer 401 may have a thickness of 30 nm to 200 nm, for example of 50 nm to 150 nm, and have a resistance of 100 Ω/□ to 10⁶ Ω/□, such as 100 Ω/□ to 10⁴ Ω/□. In some embodiments, the step of depositing the insulating aluminum zinc oxide layer comprises pulsed or non-pulsed DC sputtering in a sputter atmosphere containing 1 to 50 volume percent (also referred to as molar percent) of oxygen-containing gas, for example, a sputter atmosphere containing at least 5 volume percent of the oxygen-containing gas, such as 5 to 10 volume percent of the oxygen-containing gas. Any suitable oxygen-containing gas may be used, for example, O₂ or H₂O may be used in some embodiments. In a non-limiting example, a 100 nm thick insulating aluminum zinc oxide layer having a resistance of 80,000 Ω/□ is formed on a glass substrate by DC sputtering a zinc oxide target having an aluminum content of 0.05 weight percent (i.e., 500 ppm). In another non-limiting comparative example, a 100 nm thick insulating aluminum zinc oxide layer having a resistance of 5000 Ω/□ is formed on a glass substrate by DC sputtering a zinc oxide target having an aluminum content of 2 weight percent (i.e., 20,000 ppm). During the DC sputtering of both examples, a DC sputtering power of 2000 watts, an argon gas flow of 50 sccm and an oxygen gas flow of 2 sccm are used. Of course, any other suitable sputtering parameters may be used instead.

Optionally, one or more buffer layers (not shown) may be deposited between the n-type semiconductor layer 302 and the insulating aluminum zinc oxide layer 401.

A second electrode 402, also referred to as a transparent top electrode, is further deposited over the insulating layer. The transparent top electrode 402 may comprise any suitable transparent conductive material, for example Indium Titanium Oxide (ITO) having an atomic ratio of indium to tin from 1:1 to 20:1, doped ZnO having 1-5 weight percent aluminum, doped SnO, or a combination thereof. Other commonly used transparent conductive oxides including gallium doped ZnO and/or boron doped ZnO may also be used. The second electrode 402 may be deposited by sputtering such as pulsed or non-pulsed DC or AC sputtering, CVD, electroplating, or any other suitable methods. The resistivity of the resulting second electrode 402 may be less than 50 Ω/□, preferably less than 10 Ω/□.

Further, one or more optional antireflection (AR) films (not shown) may be deposited over the transparent top electrode 402. In some embodiments, current collection grid lines 502 may be deposited over the top conducting oxide 402 or the one or more optional antireflection films to optimize the light absorption of the solar cell.

Alternatively, the solar cell may be formed in reverse order. In this configuration, a transparent electrode is deposited over a substrate, followed by depositing the RAZO layer over the transparent electrode, depositing the n-type semiconductor layer over the RAZO layer, depositing at least one p-type semiconductor absorber layer over the n-type semiconductor layer, and depositing a top electrode, such as a Mo electrode, over the at least one p-type semiconductor absorber layer. The substrate may be a transparent substrate (e.g., glass) or opaque (e.g., metal). If the substrate used is opaque, then the initial substrate may be delaminated after the steps of depositing the stack of the above described layers, and then bonding a glass or other transparent substrate to the transparent electrode of the stack.

More preferably, the steps of depositing the first electrode 200 over the substrate 100 (preferably a web substrate in this embodiment), depositing the at least one p-type semiconductor absorber layer 301, depositing the n-type semiconductor layer 302, depositing the insulating zinc oxide layer 401, and depositing the second electrode 402 are conducted in corresponding process modules of a plurality of independently isolated, connected process modules without breaking vacuum, while passing the metallic web substrate 100 from an input module to an output module through the plurality of independently isolated, connected process modules. The web substrate 100 continuously extends from the input module to the output module while passing through the plurality of the independently isolated, connected process modules. Each of the process modules may include one or more sputtering targets for sputtering material over the web substrate 100.

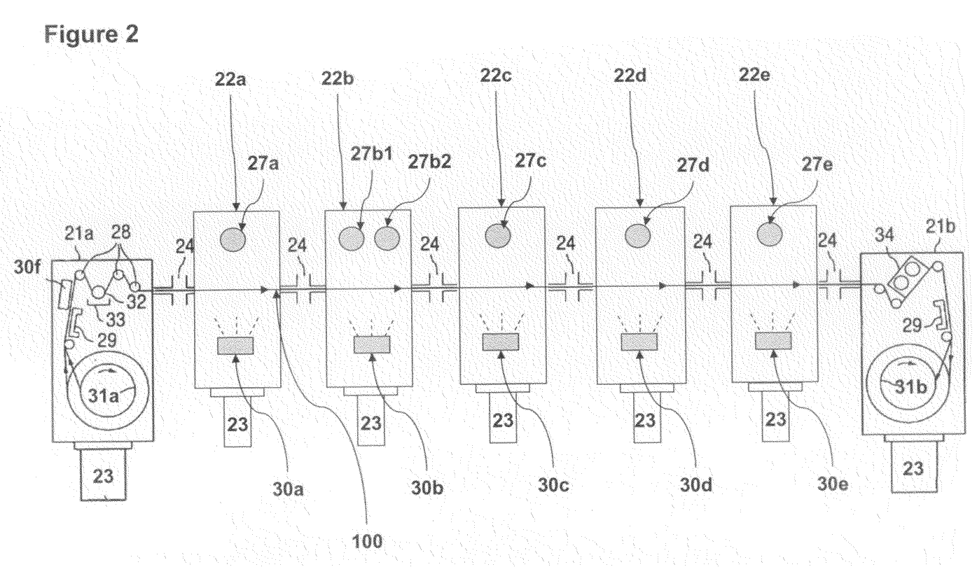

For example, a modular sputtering apparatus for making the solar cell, as illustrated in FIG. 2 (top view), may be used for depositing the layers. The apparatus is equipped with an input, or load, module 21a and a symmetrical output, or unload, module 21b. Between the input and output modules are process modules 22a, 22b, 22c, 22d and 22e. The number of process modules 22 may be varied to match the requirements of the device that is being produced. Each module has a pumping device 23, such as vacuum pump, for example a high throughput turbomolecular pump, to provide the required vacuum and to handle the flow of process gases during the sputtering operation. Each module may have a number of pumps placed at other locations selected to provide optimum pumping of process gases. The modules are connected together at slit valves 24, which contain very narrow low conductance isolation slots to prevent process gases from mixing between modules. These slots may be separately pumped if required to increase the isolation even further. Other module connectors 24 may also be used. Alternatively, a single large chamber may be internally segregated to effectively provide the module regions, if desired. U.S. Published Application No. 2005/0109392 A1 (“Hollars”), filed on Oct. 25, 2004, discloses a vacuum sputtering apparatus having connected modules, and is incorporated herein by reference in its entirety.

The web substrate 100 is moved throughout the machine by rollers 28, or other devices. Additional guide rollers may be used. Rollers shown in FIG. 2 are schematic and non-limiting examples. Some rollers may be bowed to spread the web, some may move to provide web steering, some may provide web tension feedback to servo controllers, and others may be mere idlers to run the web in desired positions. The input spool 31a and optional output spool 31b thus are actively driven and controlled by feedback signals to keep the web in constant tension throughout the machine. In addition, the input and output modules may each contain a web splicing region or device 29 where the web 100 can be cut and spliced to a leader or trailer section to facilitate loading and unloading of the roll. In some embodiments, the metal web 100, instead of being rolled up onto output spool 31b, may be sliced into solar modules by the web splicing device 29 in the output module 21b. In these embodiments, the output spool 31b may be omitted. As a non-limiting example, some of the devices/steps may be omitted or replaced by any other suitable devices/steps. For example, bowed rollers and/or steering rollers may be omitted in some embodiments.

Heater arrays 30 are placed in locations where necessary to provide web heating depending upon process requirements. These heaters 30 may be a matrix of high temperature quartz lamps laid out across the width of the web. Infrared sensors provide a feedback signal to servo the lamp power and provide uniform heating across the web. In one embodiment, as shown in FIG. 2, the heaters are placed on one side of the web 100, and sputtering targets 27a-e are placed on the other side of the web 100. Sputtering targets 27a-e may be mounted on dual cylindrical rotary or planar magnetron(s) sputtering sources.

After being pre-cleaned, the web substrate 100 may first pass by heater array 30f in module 21a, which provides at least enough heat to remove surface adsorbed water. Subsequently, the web can pass over roller 32, which can be a special roller configured as a cylindrical rotary magnetron. This allows the surface of electrically conducting (metallic) webs to be continuously cleaned by DC, AC, or RF sputtering as it passes around the roller/magnetron. The sputtered web material is caught on shield 33, which is periodically changed. Optionally, another roller/magnetron may be added (not shown) to clean the back surface of the web. Direct sputter cleaning of a conductive web will cause the same electrical bias to be present on the web throughout the machine, which, depending on the particular process involved, might be undesirable in other sections of the machine. The biasing can be avoided by sputter cleaning with linear ion guns instead of magnetrons, or the cleaning could be accomplished in a separate smaller machine prior to loading into this large roll coater. Also, a corona glow discharge treatment could be performed at this position without introducing an electrical bias.

Next, the web 100 passes into the process module 22a through valve 24, for depositing the conductive layer 202. Following the direction of the imaginary arrows along the web 100, the full stack of layers may be deposited in one continuous process.

The web 100 then passes into the next process module, 22b, for deposition of the at least one p-type semiconductor absorber layer 301. In a preferred embodiment shown in FIG. 2, the step of depositing the at least one p-type semiconductor absorber layer 301 includes reactively alternating current (AC) magnetron sputtering the semiconductor absorber layer from at least one pair of two conductive targets 27b1 and 27b2, in a sputtering atmosphere that comprises argon gas and a selenium-containing gas. In some embodiment, the pair of two conductive targets 27b1 and 27b2 comprise the same targets. For example, each of the at least two conductive targets 27b1 and 27b2 comprises copper, indium and gallium, or comprises copper, indium and aluminum. The selenium-containing gas may be hydrogen selenide or selenium vapor. In other embodiments, targets 27b1 and 27b2 may comprise different materials from each other. The radiation heaters 30 maintain the web at the required process temperature, for example, around 400-800° C., for example around 500-600° C., which is preferable for the CIS based alloy deposition.

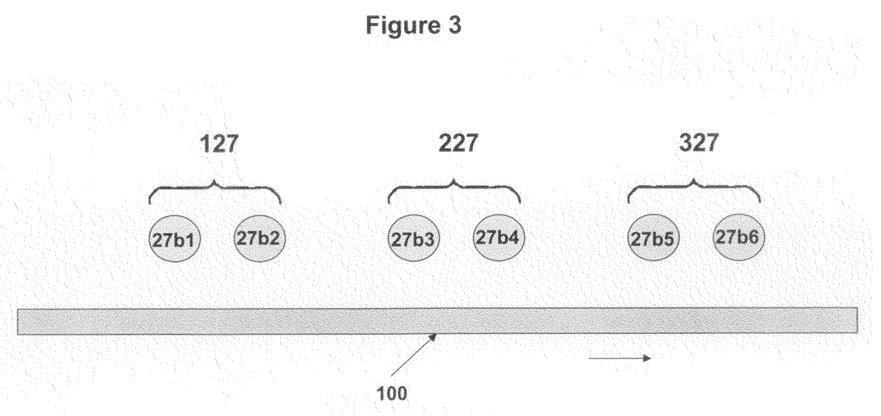

In some embodiments, at least one p-type semiconductor absorber layer 301 may comprise graded CIS based material. In this embodiment, the process module 22b further comprises at least two more pairs of targets (227 and 327), as illustrated in FIG. 3. The first magnetron pair 127 (27b1 and 27b2) are used to sputter a layer of copper indium diselenide while the next two pairs 227, 327 of magnetrons targets (27b3, 27b4 and 27b5, 27b6) sputter deposit layers with increasing amounts of gallium (or aluminum), thus increasing and grading the band gap. The total number of targets pairs may be varied, for example may be 2-10 pairs, such as 3-5 pairs. This will grade the band gap from about 1 eV at the bottom to about 1.3 eV near the top of the layer. Details of depositing the graded CIS material is described in the Hollars published application, which is incorporated herein by reference in its entirety.

Optionally, one or more process modules (not shown) may be added between the process modules 21a and 22a to sputter a back side protective layer over the back side of the substrate 100 before the electrode 200 is deposited on the front side of the substrate. U.S. patent application Ser. No. 12/379,428 (Attorney Docket No. 075122/0139) titled “Protective Layer for large-scale production of thin-film solar cells” and filed on Feb. 20, 2009, describes such a deposition process and is hereby incorporated by reference in its entirety. Further, one or more barrier layers 201 may be sputtered over the front side of the substrate 100 in the process module(s) added between the process modules 21a and 22a. Similarly, one or more process modules (not shown) may be added between the process modules 22a and 22b, to sputter one or more adhesion or barrier layers 203 between the conductive layer 202 and the CIGS layer 301.

The web 100 may then pass into the process module 22c, for depositing the n-type semiconductor layer 302. Any suitable type of sputtering sources 27c may be used, for example, rotating or planar AC magnetron(s), or RF magnetron(s),etc. Extra magnetron stations (not shown), or extra process modules (not shown) could be added for sputtering the optional one or more AR layers.

Next, the web 100 may pass into the process module 22d for depositing the insulating aluminum zinc oxide layer 401. Preferably, the insulating aluminum zinc oxide layer 401 may be deposited by pulsed DC or non-pulsed DC sputtering a zinc oxide target 27d comprising 100 ppm to 5000 ppm aluminum, preferably 100 ppm to 2000 ppm aluminum such as 500 ppm to 1200 ppm. Alternatively, the insulating aluminum zinc oxide layer 401 may be deposited by AC sputtering if desired. A sputter atmosphere containing 1 to 50 volume percent of oxygen-containing gas may be used. For example, the sputter atmosphere may contain at least 5 volume percent of the oxygen-containing gas, such as 5 to 10 volume percent of the oxygen-containing gas. Any suitable oxygen-containing gas may be used, for example, O₂ or H₂O may be used in some embodiments. The resulting insulating aluminum zinc oxide layer 401 may have a thickness of 30 nm to 200 nm, for example of 50 nm to 150 nm, and have a resistance of 100 Ω/□ to 10⁶ Ω/□, such as 100 Ω/□ to 10⁴ Ω/□.

A second electrode 402, also referred to as a transparent top electrode, is further deposited over the insulating aluminum zinc oxide layer 401, in process module 22e by sputtering from target 27e. Finally, the web 100 passes into output module 21b, where it is either wound onto the take up spool 31b, or sliced into solar cells using cutting apparatus 29. While sputtering was described as the preferred method for depositing all layers onto the substrate, some layers may be deposited by MBE, CVD, evaporation, plating, etc., while, preferably, the CIS based alloy is reactively sputtered.

It is to be understood that the present invention is not limited to the embodiment(s) and the example(s) described above and illustrated herein, but encompasses any and all variations falling within the scope of the appended claims. For example, as is apparent from the claims and specification, not all method steps need be performed in the exact order illustrated or claimed, but rather in any order that allows the proper formation of the solar cells of the present invention.

What is claimed is:

1. A solar cell, comprising:
a first electrode located over a substrate;
at least one p-type semiconductor absorber layer located over the first electrode, the p-type semiconductor absorber layer comprising a copper indium selenide (CIS) based alloy material;
an n-type semiconductor layer located over the p-type semiconductor absorber layer;
an insulating aluminum zinc oxide layer located over the n-type semiconductor layer, the insulating aluminum zinc oxide having an aluminum content of 100 ppm to 5000 ppm; and
a second electrode over the insulating aluminum layer, the second electrode being transparent and electrically conductive.

2. The solar cell of claim 1, wherein the insulating aluminum zinc oxide layer has an aluminum content of 100 ppm to 2000 ppm.

3. The solar cell of claim 2, wherein the insulating aluminum zinc oxide layer has an aluminum content of 500 ppm to 1200 ppm.

4. The solar cell of claim 1, wherein the insulating aluminum zinc oxide layer has a thickness of 30 nm to 200 nm.

5. The solar cell of claim 1, wherein the insulating aluminum zinc oxide layer has a resistance of 100 Ω/□ to 10⁶ Ω/□, and wherein the insulating aluminum zinc oxide layer is deposited by pulsed or non-pulsed DC sputtering.

6. The solar cell of claim 5, wherein the insulating aluminum zinc oxide layer has a resistance of 100 Ω/□ to 10⁴ Ω/□.

7. The solar cell of claim 1, wherein the CIS based alloy material is selected from copper indium diselenide, copper indium gallium diselenide, or copper indium aluminum diselenide.

8. A method of manufacturing a solar cell, comprising:
depositing a first electrode over a substrate;
depositing at least one p-type semiconductor absorber layer over the first electrode, the p-type semiconductor absorber layer comprising a copper indium selenide (CIS) based alloy material;
depositing an n-type semiconductor layer over the p-type semiconductor absorber layer to form a p-n junction;
depositing an insulating aluminum zinc oxide layer located over the n-type semiconductor layer, the insulating aluminum zinc oxide having an aluminum content of 100 ppm to 5000 ppm; and
depositing a second electrode over the n-type semiconductor layer, the second electrode being transparent and electrically conductive.

9. The method of claim 8, wherein the step of depositing the insulating aluminum zinc oxide comprises pulsed or non-pulsed DC sputtering or AC sputtering.

10. The method of claim 9, wherein the step of depositing the insulating aluminum zinc oxide layer comprises pulsed or non-pulsed DC sputtering an aluminum doped zinc oxide target having an aluminum content of 100 ppm to 5000 ppm.

11. The method of claim 9, wherein the step of depositing the insulating aluminum zinc oxide layer comprises pulsed or non-pulsed DC sputtering an aluminum doped zinc oxide target having an aluminum content of 100 ppm to 2000 ppm.

12. The method of claim 8, wherein the step of depositing the insulating aluminum zinc oxide layer comprises pulsed or non-pulsed DC sputtering in a sputter atmosphere containing 1 to 50 volume percent of oxygen-containing gas.

13. The method of claim 12, wherein the step of the insulating aluminum zinc oxide layer comprises pulsed or non-pulsed DC sputtering in a sputter atmosphere comprising argon gas with 5 to 10 volume percent of the oxygen-containing gas.

14. The method of claim 13, wherein the oxygen-containing gas is O₂ or H₂O.

15. The method of claim 8, wherein the insulating aluminum zinc oxide layer has a thickness of 30 nm to 200 nm.

16. The method of claim 8, wherein the CIS based alloy material is selected from copper indium diselenide, copper indium gallium diselenide, copper indium aluminum diselenide, or combination thereof.

17. The method of claim 8, wherein the steps of depositing the first electrode, depositing the at least one p-type semiconductor absorber layer, depositing the n-type semiconductor layer, depositing the insulating zinc oxide layer, and depositing the second electrode are performed by DC or AC sputtering in a same sputtering apparatus without breaking vacuum.

18. A method of depositing an insulating aluminum zinc oxide layer, comprising pulsed or non-pulsed DC sputtering an aluminum doped zinc oxide target having an aluminum content of 100 ppm to 5000 ppm, wherein the insulating aluminum zinc oxide layer has a resistance of 100 Ω/□ to 10⁶ Ω/□.

19. A method of claim 18, wherein the aluminum doped zinc oxide target has an aluminum content of 100 ppm to 2000 ppm, and wherein the insulating aluminum zinc oxide layer has a resistance of 100 Ω/□ to 10⁴ Ω/□.

20. A method of claim 18, wherein the step of pulsed or non-pulsed DC sputtering is conducted in a sputter atmosphere comprising argon gas with 5 to 10 volume percent of oxygen-containing gas.

21. A sputtering target configured for DC or AC sputtering, comprising aluminum doped zinc oxide having an aluminum content of 100 ppm to 5000 ppm.

22. The sputtering target of claim 21, wherein:
the sputtering target is mounted in a pulsed or non-pulsed DC sputtering system; and
the aluminum doped zinc oxide has an aluminum content of 100 ppm to 2000 ppm.
